(19) United States
(12) Patent Application Publication
(10) Pub. No.: US 2012/0075782 A1
(43) Pub. Date: Mar. 29, 2012

(54) FLEXIBLE DISPLAY AND ELECTRONIC DEVICE HAVING THE SAME

(75) Inventors: WEI WU, Shenzhen City (CN); XIN YANG, Shenzhen City (CN)

(73) Assignees: HON HAI PRECISION INDUSTRY CO., LTD., Tu-Cheng (TW); FU TAI HUA INDUSTRY (SHENZHEN) CO., LTD., ShenZhen City (CN)

(21) Appl. No.: 13/161,475

(22) Filed: Jun. 15, 2011

(30) Foreign Application Priority Data
Sep. 28, 2010 (CN) 201010294836.9

(51) Int. Cl. H05K 7/00

(52) U.S. Cl. 361/679.01

(57) ABSTRACT

An electronic device includes a host and a flexible display connected to the host. The flexible display includes a flexible screen and a base for supporting the flexible screen. The base is configured to switch the flexible screen between an unfurled state and a furled state.

### BACKGROUND

1. Technical Field

The present disclosure relates to displays and, particularly, to a flexible display and an electronic device having the same.

2. Description of Related Art

Electronic devices such as portable computer, usually includes a display for displaying images. In order for the user to hold the electronic devices in their hand, the size of the display is considerably reduced. Therefore, smaller graphic panels with reduced graphic resolution have been developed. By virtue of reducing both the size of the display panel and the resolution, less information is now visible to the user.

Therefore, what is needed is an electronic device with a display to overcome the described limitations.

### BRIEF DESCRIPTION OF THE DRAWINGS

FIG. 1 is a schematic diagram of an electronic device having a flexible display, in accordance with an embodiment, in a furled state.

FIG. 2 is a schematic diagram of the electronic device of FIG. 1, in an unfurled state.

FIG. 3 is a cross-sectional view of the electronic device of FIG. 1, taken along line III-III of FIG. 2.

FIG. 4 is similar to FIG. 3, but showing a scroll being fixed on a fixed portion of a second housing of the electronic device of FIG. 1, in accordance with a second embodiment.

FIG. 5 is similar to FIG. 4, but showing a hook being fixed on the second housing of the electronic device of FIG. 4.

### DETAILED DE SCRIPTION

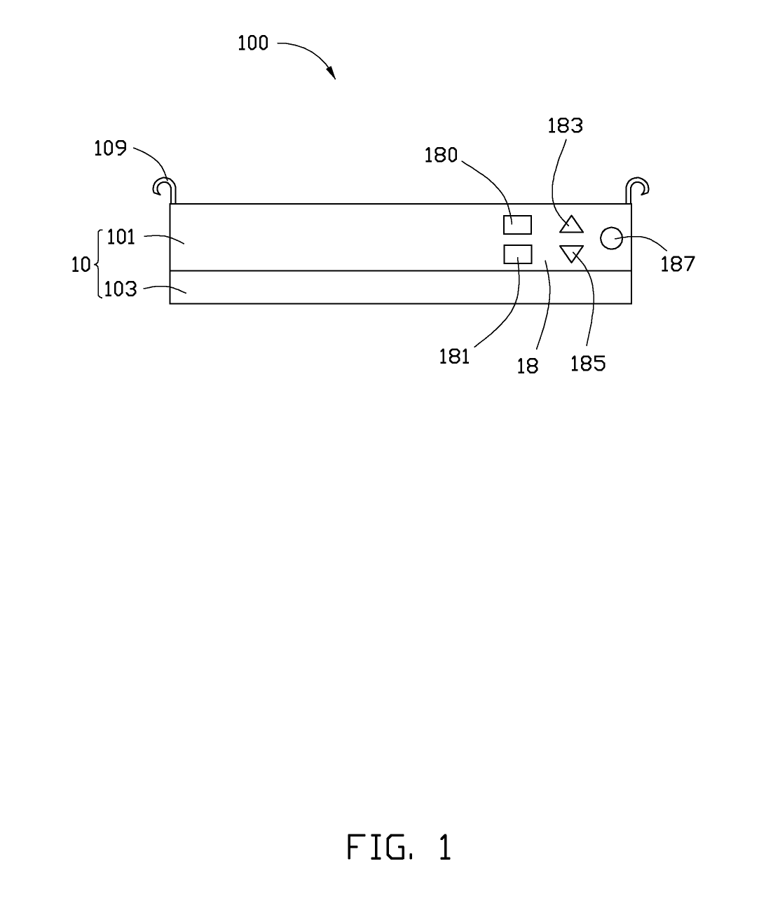

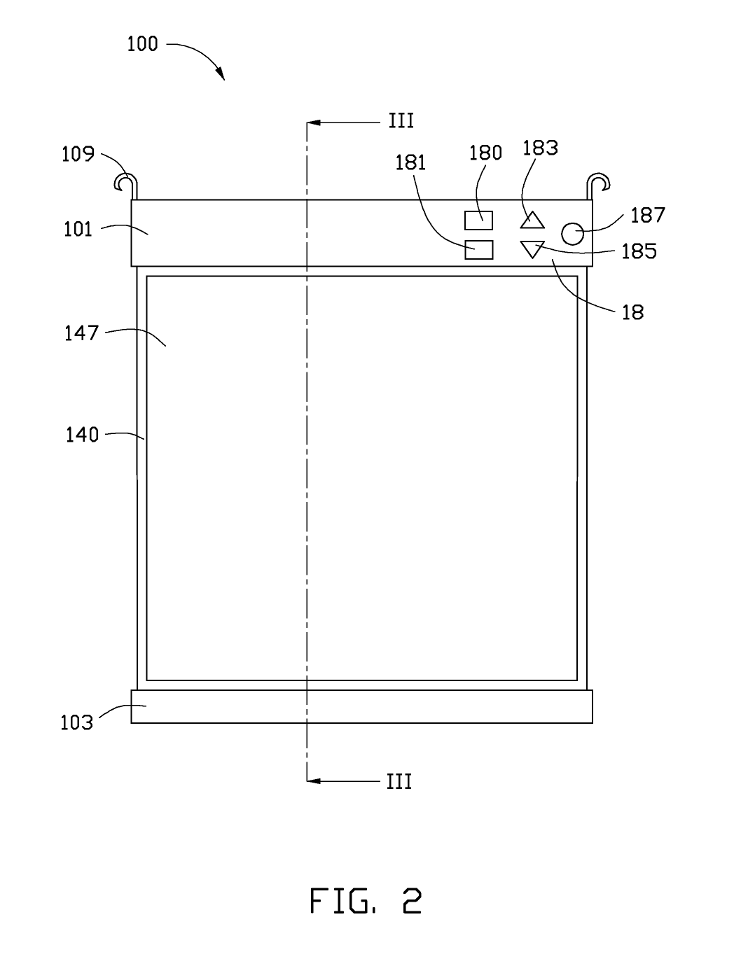

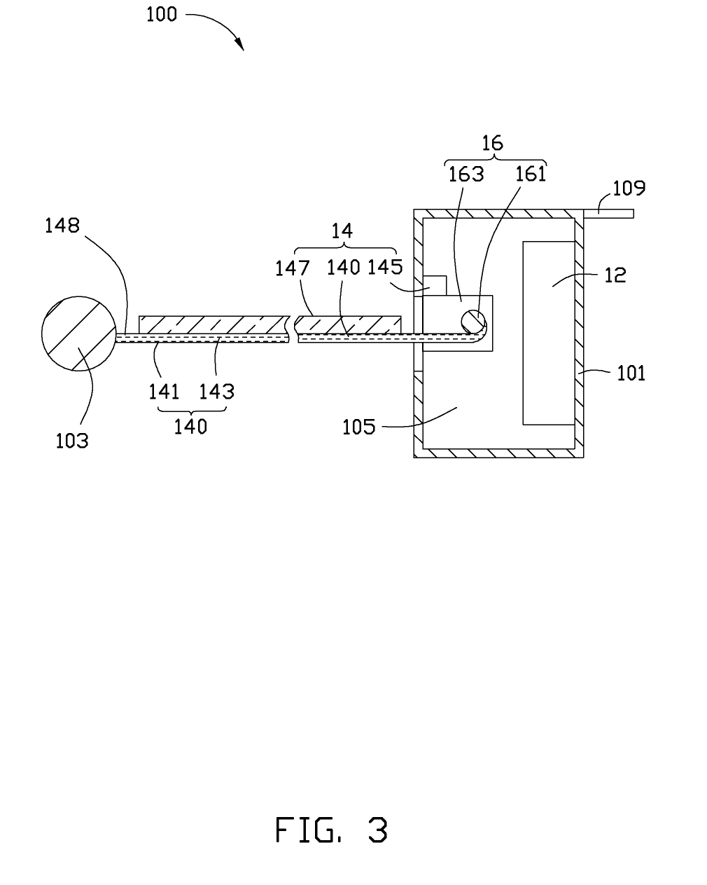

Referring to FIGS. 1-3, an embodiment of an electronic device 100 is illustrated. The electronic device 100 includes a first housing 10, a host 12, a flexible display 14, and a rotation portion 16.

The first housing 10 includes an upper portion 101 and a lower portion 103 engaged with the upper portion 101. A receiving chamber 105 is defined in the upper portion 101, and is configured to receive the host 12, the flexible display 14, and the rotation portion 16. Furthermore, a number of hooks 109 are mounted on an outer surface of the upper portion 101, used to hang the electronic device 100 on the wall, or a support. In other embodiment, the hooks 109 can also be mounted on the outer surface of the lower portion 103.

The host 12 is fixed on the upper portion 101, and is configured to generate video signal.

The flexible display 14 includes a flexible screen 147, a base 140 for supporting the flexible screen 147, and a power module 145 electrically connected to the flexible screen 147. The base 140 is configured to switch the flexible screen 147 between an unfurled state and a furled state. The base 140 includes a flexible housing 141 and an electro-rheological fluid (EF) 143. A receiving space 148 is formed within the flexible housing 141, and is filled with the EF 143. One end of the flexible housing 141 is fixed on the upper portion 101, and an opposite end is fixed on the lower portion 103. The power module 145 provides power for the flexible display 14. In detail, the power module 145 is configured to provide an electric field for the EF 143, and provide the power for the flexible screen 147. The flexible screen 147 is adhered to an upper surface of the flexible housing 141. In one embodiment, the flexible screen 147 is an organic light emitting diode (OLED) screen. When the power module 145 applies an electric field on the EF 143, the EF 143 will keep in a solid state and thus to prevent the flexible screen 147 from furling. The base 140 can be unfurled as a flat panel carrier to perform the flexible screen 147 as a flat panel display. In addition, when the power module 145 stops to provide the electric field on the EF 143, the EF 143 will keep in a liquid state, causing the flexible screen 147 to be easily furled by the base 140.

The rotation portion 16 includes a scroll 161 and a motor 163 for driving the scroll 161 to rotate clockwise/counter-clockwise. In one embodiment, two ends of the scroll 161 are pivoted onto the upper portion 101. In other embodiments, the two ends of the scroll 161 can be pivoted on the lower portion 103. The motor 163 is fixed on the upper portion 101, and is electrically connected to the host 12. One end of the flexible housing 141 is fixed on the scroll 161, and an opposite end is fixed on the lower portion 103. When the EF 143 is in the liquid state and the motor 163 rotates the scroll 161. The flexible housing 141 will be coiled on the scroll 161, and the lower portion 103 will be moved closer to the upper portion 101 thereby providing a convenient way for a user to engage the upper portion 101 with the lower portion 103.

In one embodiment, when the EF 143 is in the liquid state, the scroll 161 is driven to rotate clockwise/counter-clockwise by the motor 163, the flexible housing 141 will be unfurled, and when the scroll 161 is driven to rotate counter-clockwise/clockwise by the motor 163, the flexible housing 141 will be furled.

In one embodiment, the electronic device 100 further includes a key portion 18. The key portion 18 includes a first key 180, a second key 181, a third key 183, a fourth key 185, and a fifth key 187. The first key 180 is configured to switch the host 12 between an enabled state and a disabled state. The second key 181 is configured to switch the power module 145 between an enabled state and a disabled state. The third key 183 and the fourth key 185 are configured to control the motor 163 to rotate clockwise/counter-clockwise. The fifth key 187 is configured to switch the motor 163 between an enabled state and a disabled state.

For example, when the fifth key 187 is pressed, the motor 163 will stay in the enabled state, and when the third key 183 is pressed, the scroll 161 will be driven to rotate clockwise/counter-clockwise by the motor 163, thereby causing the flexible housing 141 to be unfurled. When the fourth key 185 is pressed, the scroll 161 will be driven to rotate counter-clockwise/clockwise by the motor 163, thereby causing the flexible housing 141 to be furled. After the flexible housing 141 is completely unfurled, the user can also press the fourth key 185 or the third key 183 to control the motor 163 to rotate counter-clockwise/clockwise, thereby adjusting an extended length of the flexible housing 141.

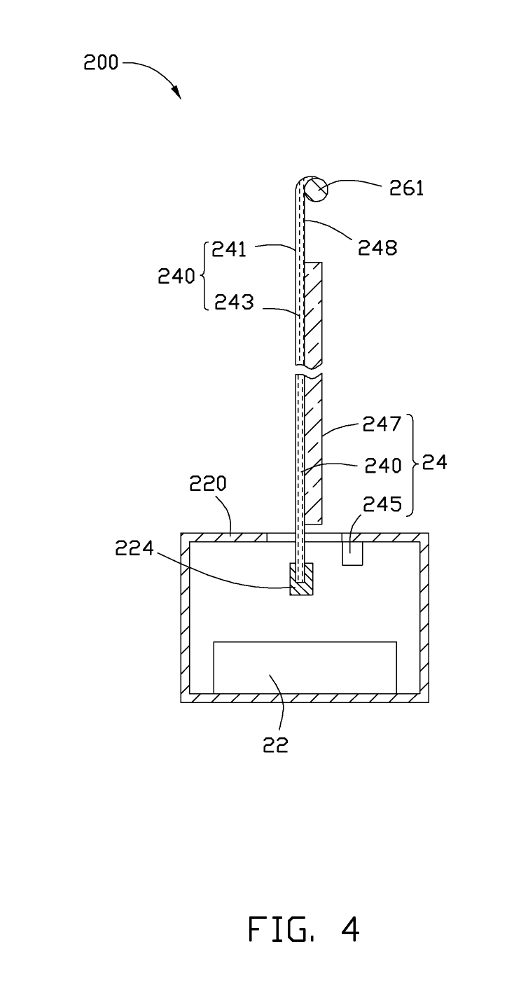

Referring to FIG. 4, an electronic device 200 in a second embodiment is illustrated. The electronic device 200 includes a host 22, a flexible display 24 and a scroll 261. A second housing 220 is placed around the host 22. The flexible display 24 includes a flexible screen 247, a base 240 for supporting the flexible screen 247, and a power module 245 electrically connected to the flexible screen 247. The base 240 includes a flexible housing 241 and an electro-rheological fluid (EF) 243 being filled within the flexible housing 241. One end of the flexible housing 241 is engaged on a fixed portion 224 of the second housing 220, and an opposite end is fixed on the scroll 261. The flexible screen 247 is adhered to the outer surface of the flexible housing 241, and is electrically connected to the host 22.

When the electronic device 200 is powered off, the EF 243 is in a liquid state, and the flexible screen 247 and the flexible housing 241 can be furled on the scroll 261, thereby providing convenience for the user to collect the electronic device 200.

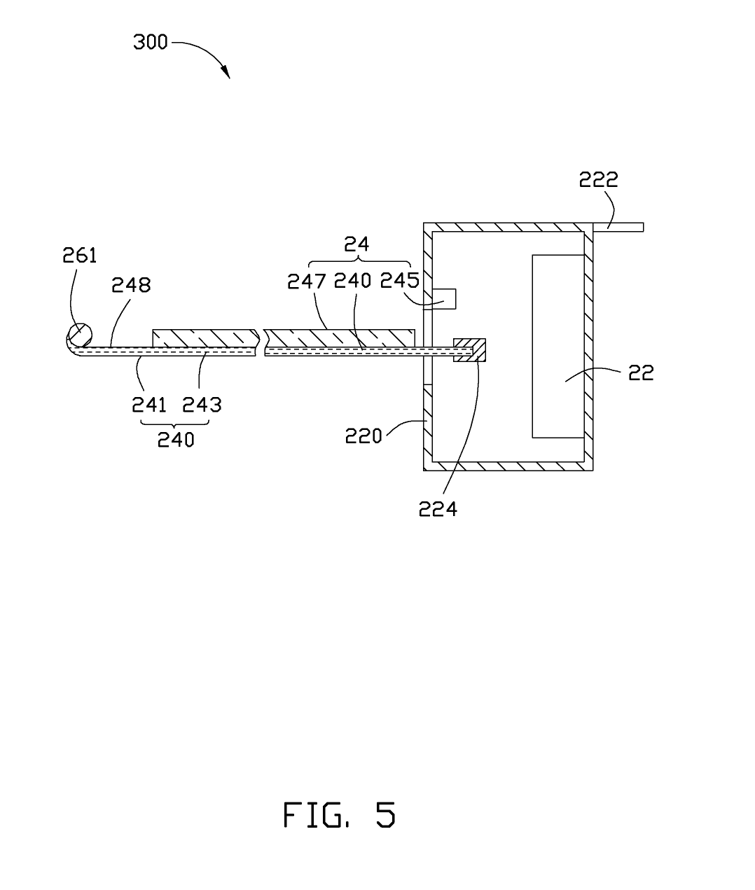

To use the electronic device 200, the flexible housing 241 is first unfurled, and the electronic device 200 is powered on. After the electronic device 200 is powered on, the EF 243 changes from the liquid state to the solid state, causing the flexible display 24 to be as a flat panel display. Furthermore, a hook 222 is mounted on the second housing 220 (as shown in FIG. 5), which is used to hang the electronic device 200 on a wall, or support.

Although the present disclosure has been specifically described on the basis of the exemplary embodiment thereof, the disclosure is not to be construed as being limited thereto. Various changes or modifications may be made to the embodiment without departing from the scope and spirit of the disclosure.

What is claimed is:

1. An electronic device comprising:
a host; and
a flexible display connected to the host, and comprising:
a flexible screen; and
a base for supporting the flexible screen, and to switch the flexible screen between an unfurled state and a furled state.

2. The electronic device as described in claim 1, wherein the flexible screen is an organic light emitting diode (OLED) screen.

3. The electronic device as described in claim 1, wherein the flexible display further comprises a power module electrically connected to the flexible screen, the base comprises a flexible housing, and electro-rheological fluid (EF) being filled within the flexible housing, when the power module applies an electric filed on the EF, the EF is in a solid state, and thus to prevent the flexible screen from furling, when the power module stops to provide the electric field on the EF, the EF is in a liquid state, causing the flexible screen to be furled by the flexible housing.

4. The electronic device as described in claim 3, wherein the flexible screen is adhered to an outer surface of the flexible housing.

5. The electronic device as described in claim 3, further comprising a scroll, wherein one end of the flexible housing is fixed on the scroll, the scroll is configured to switch the flexible housing between an unfurled state and a furled state.

6. The electronic device as described in claim 5, wherein a second housing is placed around the host, one end of the flexible housing is engaged on a fixed portion of the second housing, and an opposite end is fixed on the scroll.

7. The electronic device as described in claim 5, further comprising a first housing for receiving the flexible display and the host, wherein the first housing comprises an upper portion and a lower portion engaged with the upper portion, a receiving chamber is defined in the upper portion, and is configured to receive the flexible display and the host.

8. The electronic device as described in claim 7, wherein two ends of the scroll are pivoted onto the upper portion.

9. The electronic device as described in claim 7, further comprising a hook mounted on the upper portion, wherein the hook is configured to hang the electronic device.

10. The electronic device as described in claim 7, wherein an opposite end of the flexible housing is fixed on the upper portion.

11. The electronic device as described in claim 7, further comprising a motor to control the scroll to rotate clockwise/counter-clockwise, wherein the motor is fixed on the upper portion, and two ends of the scroll are pivoted onto the upper portion.

12. The electronic device as described in claim 11, further comprising a key portion mounted on the upper portion or the lower portion, wherein the key portion comprises a first key to switch the host between an enabled state and a disabled state, a second key to switch the power module between an enabled state and a disabled state, a third key and a fourth key to control the motor to rotate clockwise/counter-clockwise, and a fifth key to switch the motor between an enabled state and a disabled state.

13. A flexible display comprising:
a flexible screen; and
a base for supporting the flexible screen, comprising:
a flexible housing;
electro-rheological fluid (EF) being filled within the flexible housing; and
a power module electrically connected to the flexible screen;
wherein when the power module applies an electric filed on the EF, the EF is in a solid state to prevent the flexible screen from furling, when the power module stops to provide the electric field on the EF, the EF is in a liquid state, causing the flexible screen to be furled by the flexible housing.

14. The flexible display as described in claim 13, wherein the flexible screen is an organic light emitting diode (OLED) screen.

15. The flexible display as described in claim 13, wherein the flexible screen is adhered to an outer surface of the flexible housing.
